(19) United States
(12) Patent Application Publication
(10) Pub. No.: US 2026/0217538 A1
(43) Pub. Date: Jul. 30, 2026

(54) GRAPHENE SLURRY AND METHOD FOR THE FABRICATION OF A FLEXIBLE THERMOELECTRIC GENERATOR THEREFROM

(71) Applicant: UNIVERSIDAD DE LOS ANDES, Bogotá (CO)

(72) Inventors: Johanns Mauricio CANAVAL RUIZ, Bogotá (CO); Camilo Andrés BALAGUERA BONITTO, Bogotá (CO); Ever Eduardo QUINTERO CAMARGO, Berango (ES); Daniel Esteban OLAYA CORTES, Cali (CO); Yenny Rocio HERNANDEZ PICO, Bogotá (CO)

(21) Appl. No.: 19/141,181

(22) PCT Filed: Dec. 19, 2023
(86) PCT No.: PCT/IB2023/062956

§ 371 Date: Jun. 19, 2025

Related U.S. Application Data
(60) Provisional application No. 63/476,227, filed on Dec. 20, 2022.

(51) Int. Cl. C01B 32/194; B82Y 40/00; H10N 10/01; H10N 10/17; H10N 10/852; H10N 10/855

(52) U.S. Cl. CPC C01B 32/194; H10N 10/01; H10N 10/17; H10N 10/852; H10N 10/855; B82Y 40/00; C01B 2204/22; C01B 2204/24

(57) ABSTRACT

The present disclosure relates to a graphene slurry (1), a thermoelectric material, and a thermoelectric device (2). The graphene slurry (1) is characterized in that it comprises a high-concentration yield of graphene and can be used for screen printing on different support materials, such as fabric, to obtain a thermoelectric device (2). Furthermore, the present disclosure relates to the methods for producing said graphene slurry (1), and the methods for obtaining a thermoelectric material and a thermoelectric generator therefor.

### FIELD OF THE INVENTION

The present disclosure is related to the field of materials science and is of application in the areas of energy production for wearable devices, flexible devices, and thermoelectric devices. Particularly, it relates to a graphene slurry, a thermoelectric material, and a thermoelectric device and the methods for producing them.

### BACKGROUND OF THE INVENTION

Graphene is a two-dimensional (2D) allotrope of carbon, composed of a single layer of carbon atoms arranged in a hexagonal lattice structure, often referred to as a honeycomb. Although such an atomically thin structure is not commonly found as a standalone material in nature, graphene can be synthetized or isolated from naturally occurring allotropes, such as graphite, which is composed of many stacked layers of graphene. In bulk graphite, the individual graphene layers are held together by weak Van der Waals forces.

Unlike the weak off-plane bonds that are formed between the layered graphene in graphite, the carbon atoms of isolated graphene form strong in-plane covalent bonds with each other through sp₂ orbital hybridization. This configuration contributes to the remarkable properties of graphene. Accordingly, graphene has been regarded as one of the most promising materials due to its exceptional properties and potential for a wide range of applications. Some of the best-known properties of graphene are its mechanical strength, reduced weight, chemical stability, biocompatibility, high electrical and thermal conductivity, and flexibility. Such characteristics are advantageous for flexible electronics, wearable devices, and other applications requiring bendable materials. In addition, its high charge carrier mobility renders it ideal for electronics and heat management. These attributes, combined with its chemical stability and biocompatibility, offer promising avenues in fields such as optoelectronics, nanoelectronics, energy conversion, and energy storage devices.

The isolation of graphene involves the separation of individual layers of graphene from the bulk material. Layered materials, like graphite, consist of weakly stacked two-dimensional flakes forming three-dimensional structures composed of multiple graphene layers held together by van der Waals forces. To successfully exfoliate graphite into individual graphene layers, it is essential to overcome these van der Waals forces.

For example, micromechanical cleavage allows the mechanical separation of graphene layers from a graphitic material, down to a thickness of a few atomic layers or a single layer; however, this method faces important challenges regarding the graphene fraction outcome so obtained, as well as production scalability for widespread application.

Alternatively, graphene can be obtained by inserting atomic or molecular layers of a different chemical species between host graphite sheets. The intercalation process increases the distance between graphite layers, weakening the van der Waals forces between said layers, and allowing the layer separation to produce a dispersion containing expanded graphite and graphene. The graphite intercalation compounds are also known as expanded graphite.

The exfoliation process can also be assisted using a temperature gradient or by sonication. For example, the article by Hernádez et al. “High-yield production of graphene by liquid-phase exfoliation of graphite” (2008) recites the production of high-quality monolayer graphene by a non-chemical, solution-phase exfoliation of graphite in certain organic solvents.

Immersing a graphite material in a liquid medium, for example, a solvent, can facilitate the exfoliation process. Utilizing suitable solvents aids the dispersion of the graphene layers while minimizing the enthalpy of the mix composed by the solvent and graphene flakes, this is achieved by using solvents with surface tension close to that of graphene thus reducing the interaction energy.

Similarly, few-layer graphene can be obtained by electrochemical exfoliation, intercalating the ions of an electrolyte in graphite precursors subjected to high potentials. The patent document WO2020099370A1 recites a method for obtaining graphene by means of electrolytic exfoliation of a graphite material in an electrolytic cell. According to WO2020099370A1, the graphene production method allows to reduce the use of energy, time, and production costs by applying voltage in the form of alternating long, low-voltage pulses, and short, high-voltage pulses. Additionally, WO2020099370A1 recites that poorly exfoliated material can be reused without any pre-treatment through a feedback system.

Graphene dispersions can be used in the fabrication process of graphene compositions, for example, functional inks and printed layered materials. The patent document U.S. Pat. No. 9,718,972B2 refers to an ink comprising a carrier liquid with a dispersion of flakes derived from a layered material, such as graphene. The ink was used for printing by means of an inkjet printer. This strategy allows to deposit a functional ink in different types of support materials to obtain a composite layered material formed by sequential deposition of flakes derived from different layered materials, including substrates comprising a flexible material.

Furthermore, graphene dispersions can be prone to re-aggregation due to the remaining strong affinity of each single layer for each other related to the aforementioned van der Waals forces. Thus, graphene can be dispersed to improve applicability. For example, patent document CN105778571A recites a preparation method to obtain a graphene slurry. The method comprises the steps of dispersing graphene in a dispersion medium A1 to obtain a mixture B1, and then, adding a dispersing aid in the mixture Al and an aniline oligomer derivative for forming T-T bonds to obtain a mixture B2. The B2 mixture is dried to obtain an aniline oligomer derivative modified graphene composite powder, which is then dispersed in a dispersion medium A2 to obtain a graphene composite slurry.

The patent document CN108529606B also relates to a graphene slurry and preparation method thereof. The obtained graphite can be stored at room temperature and high temperature, and is prepared from natural graphite flakes, a mixed solution consisting of an intercalation agent, an auxiliary intercalation agent and an oxidant.

Graphene slurries can be used to achieve deposition of a graphene compositions in diverse support materials, which depend on the properties of the graphene composition and the nature of the support material. However, materials with high surface roughness and absorption capacity, such as fabrics, require a graphene composition and a deposition method that allows for better adhesion and better connectivity across layers.

Additionally, further attention should be paid in the designing of application-specific methods that allow to narrow the research scope of graphene-based compositions, allowing to optimize performance and functionality and eliciting a clear path to market entry.

### BRIEF DESCRIPTION

The present disclosure relates to a graphene slurry, a thermoelectric material, and a thermoelectric device and the methods for producing them. Particularly it relates to methods and embodiments for obtaining a graphene high concentration slurry and methods for producing flexible thermoelectric material, and a thermoelectric flexible generator.

The graphene slurry obtained by means of the present method comprises a concentration of a solid part in a range between 5% and 40%. The solid part is composed by few-layer graphene with a concentration in a range between 80% and 99%, wherein the few-layer graphene has a concentration of bilayer graphene greater than 80%. Said concentration allows for a high electrical and a low thermal conductivity in the off-plane direction.

Particularly, the graphene slurry can be deposited to form functional coatings in materials with high surface roughness and absorption capacity, such as fabrics. Further, said coatings can be implemented using a conductive material to obtain a flexible thermoelectric generator.

### BRIEF DESCRIPTION OF THE FIGURES

FIG. 1 shows a schematic image of a process of deposition of a graphene slurry to obtain a thermoelectric device comprising a support layer, having a first surface and a second surface, and one layer of a thermoelectric material disposed on the support layer, wherein the deposition process is screen-printing and wherein the thermoelectric material comprises at least one layer including few-layer graphene.

FIG. 2 shows a schematic image of a thermoelectric device comprising a support layer, having a first surface and a second surface, one layer of a sealing material, and one layer of a thermoelectric material.

FIG. 3 shows a schematic image of a flexible thermoelectric generator comprising polyester as a support layer, having a first surface and a second surface; a layer of gesso as a sealing material; a layer of a thermoelectric material, comprising graphene; a silver electrode as a first conductive element, disposed on at least one layer of the thermoelectric material; and a silver electrode as a second conductive element, disposed on the second surface of the support layer.

FIG. 4 shows a contact mode AFM image of graphene sheets obtained by the dispersion method of the present disclosure.

FIG. 5 shows a SEM micrograph of a thermoelectric device comprising a polyester support layer and ten layers of a thermoelectric material, wherein a portion of the thermoelectric material is embedded in the support layer.

FIG. 6 shows a cross-sectional SEM micrograph of a thermoelectric device comprising a polyester support layer, seven layers of a thermoelectric material, and three depositions of a gesso sealing material disposed between the support layer and the thermoelectric material.

FIG. 7 shows a graphic of the thermoelectric behavior of a flexible thermoelectric generator. The graphic shows the temperature difference measured between opposite faces of a flexible thermoelectric generator against the magnitude of the generated voltage.

FIG. 8 shows a diagram depicting a method for producing a graphene slurry.

FIG. 9 shows a diagram depicting an expansion process for obtaining a filtered product containing expanded graphite.

FIG. 10 shows a diagram depicting a dispersion process for obtaining a graphene slurry from a filtered product containing expanded graphite.

FIG. 11 shows a diagram depicting a method for producing a thermoelectric device.

FIG. 12 shows a diagram depicting a method for producing a flexible thermoelectric generator.

### DETAILED DESCRIPTION OF THE INVENTION

In a world defined by the ever-increasing global and individual energy consumption, there is an unprecedented opportunity to harness energy from sources that operate at near-ambient temperatures. To realize this potential, lightweight and flexible textiles and fabrics, coupled with the thermoelectric properties of graphene, present an innovative pathway. To achieve this synergy, it becomes imperative to develop a graphene composition that ensures superior adhesion to textiles. The present disclosure addresses these challenges, paving the way for groundbreaking advancements in the field of thermoelectric materials, offering a sustainable solution to meet the growing energy demands of our time.

Materials with high surface roughness and absorption capacity, such as fabrics, benefit from a graphene deposition method that allows for better adhesion, as well as an increase in the electrical and thermal properties of the material across the deposited layers. Furthermore, special considerations should be made to calculate the concentration of graphene dispersions, and achieve application-specific characteristics, such as an improved performance in energy generation.

To achieve a better adhesion and connectivity across layers in such materials, the graphene composition can be mixed to form a viscous substance that allows for a controlled process, that is, that allows for a deposition with a defined shape and known properties. The present disclosure relates to a graphene slurry (1) that allows a controlled deposition process, and a thermoelectric material (3), a thermoelectric device (2), and a flexible thermoelectric generator therefrom. The present disclosure also relates to the methods for producing them.

The graphene slurry (1) is a mixture of graphene in a liquid or solvent. Graphene is a single layer of carbon atoms arranged in a hexagonal lattice. The slurry is typically composed of dispersed graphene flakes or sheets within the liquid medium. In this sense, a first aspect of the present disclosure is related to a graphene slurry (1) comprising a solid part and a mixture of water and solvent, wherein the solid part comprises graphene including few-layer graphene (6).

Furthermore, the solid part could include a portion of graphite and expanded graphite as an expected result of the exfoliation process.

For the understanding of the present disclosure, the expression “few-layer graphene” refers to a structure comprising a stack of graphene layers wherein the number of graphene layers is lower than 5, In other words, the off-plane number of carbon atoms is lower than 5, such structure is also known as exfoliated graphite nanoplatelet. For the understanding of the present disclosure, the term “expanded graphite” refers to the collected material after graphite is subjected to an expansion process.

The solid part can be in a concentration within a range between 5% and 40%, between 7.5% and 12.5%, between 17.5% and 22.5%, between 27.5% and 32.5%. Preferably, the solid part comprises graphene including few-layer graphene (6) with a concentration in a range between 80% and 99%, between 82.5% and 92.5%, between 86.5% and 96.5%, or between 90.5% and 99%.

In an embodiment of the present disclosure, the solid part can be in a range between 25% and 35%, wherein the solid part includes a few-layer graphene (6) concentration between 80% and 99%. This allows to harness in the dispersion the properties of few-layer graphene such as flexibility, mechanical resistance, thermoelectric properties, among others, over its bulk counterpart. Additionally, the viscosity of this embodiment enables the possibility of depositing the graphene slurry on a variety of substrates.

The solid part of the graphene slurry (1) is dispersed in a mixture of water and solvent. The mixture of water and solvent actively influences the slurry characteristics, such as stability, concentration, viscosity, and chemical compatibility. In the mixture of water and a solvent, the solvent can be in a range between 60% and 90%, between 60% and 70%, between 65% and 75%, or between 80% and 90%. Preferably, the mixture of water and solvent can be in a range between 65% and 75%.

The solvent can be selected among various organic solvents. For example, the solvent can be selected among the group comprising dimethyl sulfoxide, N-Methyl-2-pyrrolidone, Dihydrolevoglucosenone, Dimethylformamide, 1-Dodecyl-2-pyrrolidone, 1,3-Dimethy-2-Imidazolidinone, 1-Vinyl-2-pyrrolidone or other polar solvent known to a person skilled in the art.

Preferably, the solvent can be selected among solvents with a surface tension between 30 mN/m and 50 mN/m, preferably between 37 mN/m and 41 mN/m. Particularly, when the solvent has a surface tension within this range, the graphite's surface energy in the mixture is minimized, promoting the exfoliation process.

According to the above, the solvent can be selected among N-Methyl-2-pyrrolidone (NMP), Dihydrolevoglucosenone (Cyrene), or Dimethylformamide (DMF), thus, allowing to minimize the energy required to overcome the van der Waals forces of the layered graphene, and allowing the graphene slurry (1) to adopt a pseudo-plastic behavior, which is desirable for deposition methods such as screen printing.

The expression “pseudo-plastic behavior” refers to a rheological characteristic observed in fluid-solid mixtures, for example, slurries. When this behavior is present, the apparent viscosity of the mixture decreases as the shear rate increases. Stated simply, when force or shear stress is applied to the slurry through actions like stirring, pumping, or other means, it becomes easier to flow due to the higher shear rates of the applied action. This phenomenon is also referred to as “shear-thinning” behavior, which arises from interactions between the solid particles and the liquid in the slurry. When subjected to shear stress, these interactions weaken or break, which facilitates the fluid flow, thus, making this behavior desirable for deposition methods such as screen printing.

The mixture of water and a solvent can comprise solvent in a range between 60% v/v and 90% v/v, and water in a range between 10% v/v and 40% v/v, aiding the deposition and solvent evaporation processes.

The graphene slurry (1) can also comprise an additive with a Seebeck coefficient magnitude near room temperature between 1 μV/K and 1000 μV/K. For example, the additive can be selected among bismuth telluride (v. gr. Bi₂Te₃), skutterudites (v. gr. CoSb₃), Organic Thermoelectric Materials, nanostructured materials (v. gr. nanowires and quantum dots), complex compounds (v. gr. clathrates and filled skutterudites), or other materials known to a person skilled in the art.

The Seebeck coefficient allows to measure the generation of electric voltage due to the Seebeck effect, which is a thermoelectric phenomenon wherein a temperature gradient across a material produces an electric voltage.

The magnitude of an induced thermoelectric voltage or electric potential difference, generated between two points in a material when there is a temperature gradient across said material, is also known as thermopower or thermoelectric power and can be measured by the Seebeck coefficient. In other words, the Seebeck coefficient quantifies how effectively a material can convert a temperature gradient into an electric voltage.

The Seebeck coefficient can be positive or negative, depending on the type of charge carriers (electrons or holes) dominating the electrical conduction in the material. When electrons are the dominant charge carriers, a negative Seebeck coefficient indicates that the material generates a negative voltage when there is a temperature gradient, and conversely, a positive Seebeck coefficient means it generates a positive voltage.

In an embodiment of the present disclosure, the additive can be Bi₂Te₃. Preferably, the Bi₂Te 3 in the graphene slurry (1) can be within a concentration in a range between 2% and 20%. This allows to increase and decrease the thermoelectric effect of the first thermoelectric material.

Due to the unique properties of graphene, for instance, electrical conductivity, thermal conductivity, mechanical strength, flexibility, transparency, chemical stability, among others, the graphene slurry (1) can be used as a basic input for producing functional materials through a transformation process.

For example, when a layer of the graphene slurry (1) is deposited on a surface and is allowed to dry (v. gr. by solvent evaporation, dehydration, or heating), it is possible to obtain a functional material capable of converting heat into electricity or vice versa.

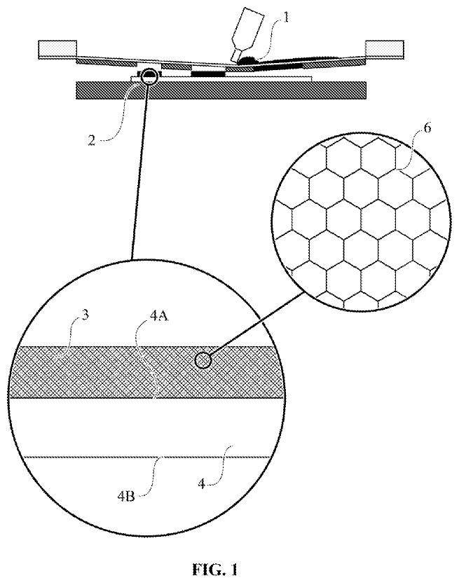

Therefore, according to FIG. 1, another aspect of the present disclosure is related to a thermoelectric material (3). The thermoelectric material (3) comprises at least one layer including few-layer graphene (6) with a concentration in a range between 80% and 99%, between 82.5% and 92.5%, between 86.5% and 96.5%, or between 90.5% and 99%.

In an embodiment of the present disclosure, the thermoelectric material (3) comprises at least one layer including few-layer graphene (6) with a concentration between 87% and 96%. When the thermoelectric material (3) comprises more than one layer including few-layer graphene (6), it is possible to tune the thermal conductivity (κ) of the overall thermoelectric material (3), that is, to have a thermal conductivity (κ) lower than 100 Wm⁻¹K⁻¹ in the direction perpendicular to the plane.

The thermal conductivity (κ) of a given material quantifies how efficiently a material can transfer thermal energy (heat) through its structure when there is a temperature gradient across it. In other words, it indicates how well a material conducts heat from a region of higher temperature to a region of lower temperature.

In another embodiment of the present disclosure, the thermoelectric material (3) comprises at least one layer including few-layer graphene (6) with a concentration between 80% and 99%.

In another embodiment of the present disclosure, the thermoelectric material (3) comprises at least one layer including few-layer graphene (6) with a concentration between than 80% and 99%, wherein more than 80% of the concentration of the few-layer graphene (6) corresponds to monolayer and bilayer graphene.

The thermoelectric material (3) of the present disclosure further comprises an additive with a material with a Seebeck coefficient similar or higher than 50 μV/K. Said additive can have a concentration in a range between 2% and 20%, for example, bismuth telluride (Bi₂Te₃), or other materials known to a person skilled in the art. Including an additive with a Seebeck coefficient similar or higher than 50 μV/K allows to tune the Seebeck coefficient of the graphite slurry, permitting to control the magnitude and sign of the electrical voltage produced in a device comprising the graphene slurry (1).

To some extent, the thermoelectric material (3) can be brittle and could require a support structure. For example, the thermoelectric material (3) can be let dry on a support surface, thus, allowing the production of thermoelectric devices.

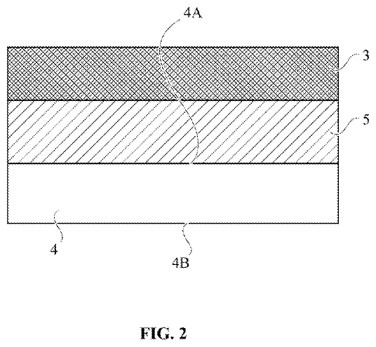

According to FIG. 2, another aspect of the present disclosure relates to a thermoelectric device (2). The thermoelectric device (2) comprises a support layer (4), with a first surface (4A) and a second surface (4B); the support layer (4) having at least one layer of thermoelectric material (3) disposed on the support layer (4); wherein, the thermoelectric material (3) comprises at least one layer including few-layer graphene (6) with a concentration in a range between 80% and 99%. This configuration allows to deposit the thermoelectric material (3) into the support layer (4). Thus, the thermoelectric features can be harnessed in the thermoelectric device (2) composed by the support layer (4) and the thermoelectric material (3).

The support layer (4) serves the purpose of providing a substrate for the thermoelectric device (2), allowing to maintain the accuracy, integrity, shape, and dimensions of the thermoelectric device (2). The support layer (4) can be formed from any material that allows the deposition of at least one coating layer of the graphene slurry (1) with a thickness between 1 μm and 500 μm, for example, deposition of a thin film, an ink, an enamel, a functional surface, or the graphene slurry (1).

The thermoelectric material (3) can be described by the printed surface area, that is, the area of the support layer (4) which is covered or occupied by the thermoelectric material (3). Also, the integrity of such thermoelectric device (2), referred as the structural soundness, durability, and ability to maintain its functional properties over time, can be measured by quantifying the superficial electrical resistance between two points separated by a known distance on the printed surface area of the thermoelectric device (2). Additionally, the surface electrical resistance of the thermoelectric material (3) provides information about how effectively electrical charge can flow across the surface of a material. In the thermoelectric device (2) the superficial electrical resistance increases as the distance is increased, such distance, measured between two points on the surface of the thermoelectric material (3). A low electrical resistance is generally desirable to minimize electrical losses and maximize thermoelectric conversion efficiency, however, it is desirable that the support layer (4) is made of an electrically isolating material.

Preferably, the support layer (4) can be formed from a flexible material, for example, the support layer (4) can be made of materials such as polymers, elastomers, paper, cardboard, polyimides, textiles, fabric, or other materials known to a person skilled in the art. When the support layer (4) is formed from a flexible material, and the thermoelectric material (3) is also formed from a flexible material, the thermoelectric device (2) can be bent, thus, it can be adapted to several shapes and surfaces, including moving surfaces. Furthermore, when the support layer (4) is formed from a flexible material, such as a textile, or a fabric, it can be used in clothing garments. According to the above, the support layer (4) can be a fabric material, for example, a fabric material including at least 50% of a polymeric material. This allows the thermoelectric device (2) to be readily available to current methods for producing clothing garments.

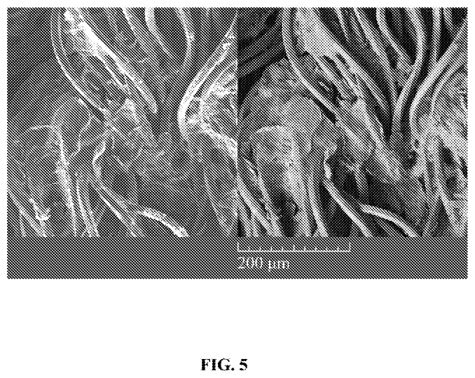

According to the above embodiment, and as shown in FIG. 5, a portion of the thermoelectric material (3) can be embedded in the support layer (4), for example, the support layer (4) can be a porous material, such as a fabric material, wherein the thermoelectric material (3) is deposited in such way that it penetrates the pores of said porous support layer (4). The pore diameter can be in a range between 0001 mm and 0.8 mm, between 0.001 mm and 0.01 mm, between 0.01 mm and 0.1 mm, between 0.1 mm and 0.2 mm, between 0.2 mm and 0.4 mm, between 0.4 mm and 0.6 mm, and between 0.6 mm and 0.8 mm.

The above configuration allows for a better backing of the thermoelectric material (3) in the thermoelectric device (2). Additionally, as the thermoelectric material penetrates and goes through the pores of the support layer (4), the perpendicular resistance of the thermoelectric device (2) decreases.

The perpendicular resistance, which depends on the support layer and on the penetration of the thermoelectric material in the support layer, can be between 0.5 kOhm and 500 kOhm, between 0.5 kOhm and 5 kOhm, between 5 kOhm and 10 kOhm, between 10 kOhm and 50 kOhm, between 50 kOhm and 100 kOhm, and between 100 kOhm and 500kOhm.

In an embodiment of the present disclosure, wherein at least one layer of the thermoelectric material (3) is disposed on the first surface (4A) of the support layer (4), and a portion of the thermoelectric material (3) is embedded between 5% and 20%, it allows for the backing of the thermoelectric material (3) while being electrically isolated from the second surface (4B) of the support layer (4).

In another embodiment, wherein at least one layer of the thermoelectric material (3) is disposed on the first surface (4A) of the support layer (4) and a portion of the thermoelectric material (3) completely penetrates into the pores of the support layer (4), the backing of the thermoelectric material (3) is improved, Additionally, such configuration allows to electrically connect both the first and the second surfaces (4A, 4B) of the support layer (4).

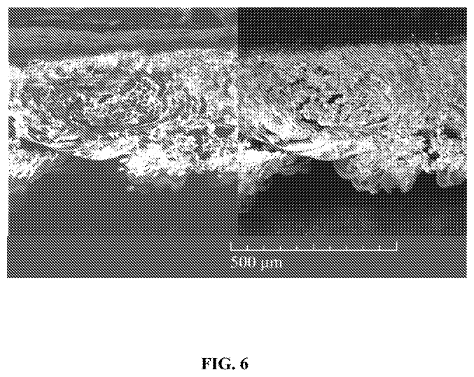

According to FIG. 6 and FIG. 2, the thermoelectric device (2) can further comprise a functional layer between the support layer (4) and the thermoelectric material (3). The functional layer can be, for example a layer of a sealing material (5) disposed between the support layer (4) and the thermoelectric material (3). The aforementioned configuration allows to modify the support layer (4) surface in order to prevent moisture and water to penetrate the support layer (4) or into the thermoelectric material (3).

The sealing material (5) can be selected among the group comprising fabric sealers, polyurethane coatings, fabric tapes, or other materials known to a person skilled in the art.

Furthermore, the sealing material (5) can be a surface primer selected among the group comprising fabric mediums, dye fixatives, stabilizers, adhesive primers, gesso, or other materials known to a person skilled in the art. The selection of a surface primer allows to modify the support layer (4) surface to reduce roughness of said surface, prevent any unwanted portion of the thermoelectric material (3) to be embedded in the support layer (4), and improve adhesion when the support layer (4) material is not adequate for the thermoelectric material (3) adhesion.

In one embodiment of the present disclosure, the thermoelectric device (2) can be used to harness an electric voltage from a temperature gradient across the thermoelectric device (2), thus, across the thermoelectric material (3). Such configuration allows to form a thermoelectric generator. To harness such electric voltage, the thermoelectric generator should also include at least two conductive elements (7A, 7B) disposed on the external surfaces of the thermoelectric device (2).

According to the present disclosure, the conductive elements (7A, 7B) can be any element known to a person skilled in the art that is capable of conducting electricity while reducing electric loses. For example, the conductive elements (7A, 7B) can be a metal electrode, such as gold electrodes, silver electrodes, aluminum electrodes, or other type of electrodes known to a person skilled in the art.

In one embodiment, the thermoelectric device (2) includes two conductive elements (7A, 7B) disposed on both external faces of the thermoelectric device (2) configuring a thermoelectric generator, that is, a first conductive element (7A) disposed on the at least one layer including few-layer graphene (6); and a second conductive element (7B) disposed on the second surface (4B) of the support layer (4). Wherein the at least one layer including few-layer graphene (6) configures a thermoelectric material (3).

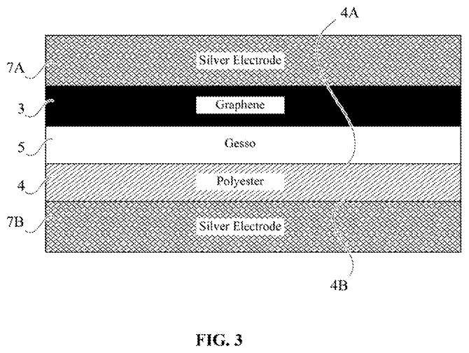

According to FIG. 3, in one embodiment of the present disclosure, the thermoelectric device (2) comprises two conductive elements (7A, 7B) disposed on both external faces of the thermoelectric device (2), and at least one layer of a sealing material (5) disposed between the support layer (4) and the thermoelectric material (3). The aforementioned configuration allows to configure a capacitor, wherein the capacitance of the thermoelectric device (2) can be modified by adding less or more layers of the sealing material (5), which, in turn, increases the distance between the two conductive elements (7A, 7B) disposed on both external faces of the thermoelectric device (2), or by modifying the thickness of the conductive elements (7A, 7B).

Furthermore, the sealing material (5) enables the possibility of modifying the load resistance of the thermoelectric device (2). This is because the sealing material (5) behaves as an additional electrical resistor between the second conductive element (7B) and the thermoelectric material (3), thus, adding more layers of the sealing material (5) also increases the load resistance of the thermoelectric device (2).

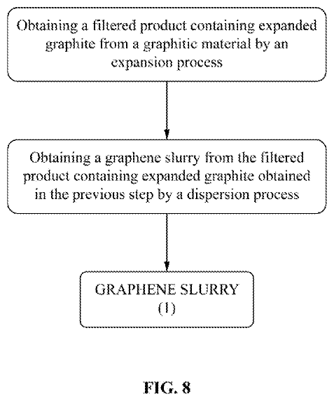

In the context of the present disclosure, the load resistance refers to the electrical resistance presented by an external circuit connected to the thermoelectric device (2) configured as a thermoelectric generator. The load resistance affects the overall performance and efficiency of the thermoelectric device (2); thus, it is important to match the load resistance with the internal resistance of the thermoelectric device (2) configured as a thermoelectric generator. This matching is often referred to as impedance matching. According to FIG. 3, another aspect of the present disclosure is related to a flexible thermoelectric generator. The flexible thermoelectric generator comprises a support layer (4) having a first surface (4A) and a second surface (4B), an optional layer of a sealing material (5) disposed on the first surface (4A) of the support material, and a layer including few-layer graphene (6) with a concentration in a range between 80% and 99%; a first conductive element (7A) disposed on the at least one layer including few-layer graphene (6); and a second conductive element (7B) disposed on the second surface (4B) of the support layer (4). This configuration allows the generation of an electric voltage. In yet another aspect, according to FIG. 8, the present disclosure is related to a method for producing a graphene slurry (1) comprising the steps of obtaining a filtered product containing expanded graphite from a graphitic material by an expansion process; and obtaining a graphene slurry (1) from the filtered product containing expanded graphite obtained in the previous step by a dispersion process.

Particularly, the obtained graphene slurry (1) includes a solid part comprising few-layer graphene (6), and a mixture of water and a solvent; wherein the few-layer graphene (6) has a concentration in a range between 80% and 99%; and wherein the mixture of water and solvent includes solvent in a range between 60% v/v and 90% v/v, and water in a range between 10% v/v and 40% v/v.

The mixture of water and solvent in the obtained graphene slurry (1) can include a solvent with a surface tension between 30 mN/m and 50 mN/m, for example, the solvent can be selected among the group comprising Cyrene, NMP, DMF, or other dipolar aprotic solvent known to a person skilled in the art. When the solvent has a surface tension between 30 mN/m and 50 mN/m the graphite's surface energy is the optimal energy per unit area, thus, interfacial tension between the solvent and graphene flakes is minimized and is sufficient to overcome the van der Waals force when two sheets are peeling apart. The expansion process allows to increase the interlayer spacing between the graphene sheets, this facilitates the exfoliation process, leading to an increase in the material's surface area and enhanced surface activity. This process involves an expanded graphite dispersion in a solvent via ultrasound exfoliation or other mechanical dispersal procedures, and an optional thickness selection through centrifugation. The expansion process can be selected among chemical intercalation, thermal expansion, solvothermal expansion, liquid-phase exfoliation, ion intercalation, electrochemical expansion, or other liquid phase expansion processes known to a person skilled in the art.

Preferably, the expansion process is an electrochemical expansion process, which involves applying an electric potential to graphite in the presence of an electrolyte. This can lead to the insertion of ions between graphene layers, causing expansion.

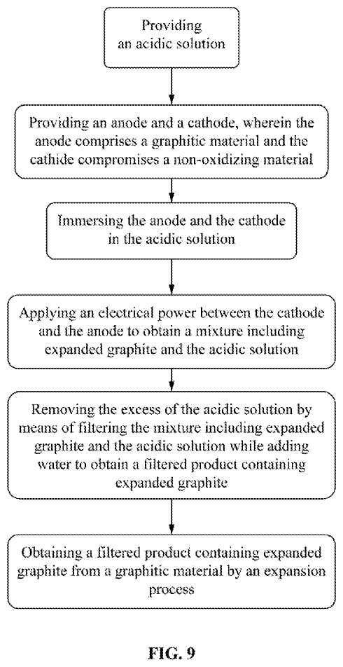

According to FIG. 9, the expansion process can also comprise the sub-steps of providing an acidic solution; providing an anode and a cathode, wherein the anode comprises a graphitic material and the cathode comprises a non-oxidizing material; immersing the anode and the cathode in the acidic solution; applying an electrical power between the cathode and the anode to obtain a mixture including expanded graphite and the acidic solution; and removing the excess of the acidic solution by means of filtering the mixture including expanded graphite and the acidic solution while adding water to obtain a filtered product containing expanded graphite. This allows to obtain pH-neutral expanded graphite that is easier to exfoliate by sonication than starting from bulk graphite.

Particularly, the acidic solution can be a highly acidic solution with a pH of approximately 1. For example, the acidic solution can be selected among hydrochloric acid (HCl), nitric acid (HNO₃), perchloric acid (HClO₄), hydrobromic acid (HBr), sulfuric acid (H₂SO₄), or other acidic solutions known to a person skilled in the art.

Preferably, the acidic solution can be H₂SO₄ with a concentration of 0.1M, or an acid with similar pH, allowing the electrolysis process to occur under an applied voltage.

Furthermore, the graphitic material can be compacted graphite, graphite foil or natural graphite crystals. This allows to hold the graphite while submerging it into the acidic solution.

The cathode non-oxidizing material can be selected among the group comprising platinum, tungsten, zirconium, or other non-oxidizing materials known to a person skilled in the art. Preferably, the cathode is a platinum wire electrode. This allows electron transport with low electrical resistance towards the acidic media resulting in the production of oxygen and ions that effectively intercalate to produce the expansion.

In an embodiment of the present disclosure, the electrical power has a voltage between 6V and 10V and a current between 0.6 A and 0.9 A. This allows oxidation and expansion of the graphite electrodes to produce the solvent-functioning graphite nanosheets, while preventing production of heat leading of the electrodes, or even graphene sample damage.

The dispersion process allows prevention of graphene agglomeration and ensures an even distribution of graphene in a liquid. For example, the dispersion process can be selected among ultrasonication, mechanical stirring, high shear mixing, ball milling, chemical stabilization, polymer assisted dispersion, other process known to a person skilled in the art or a combination of the above.

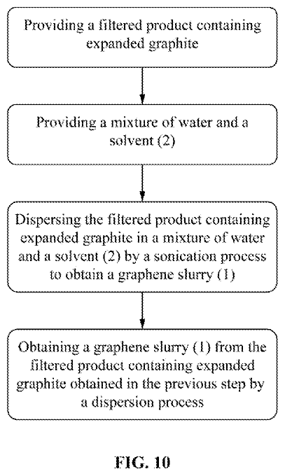

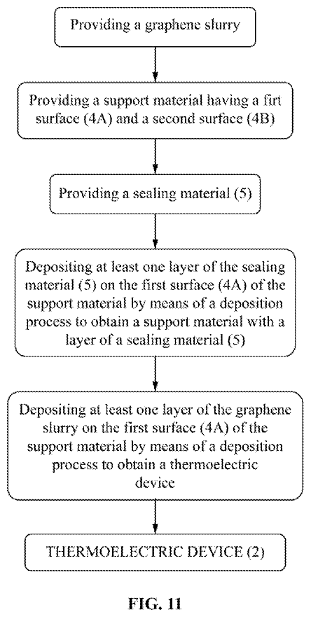

Preferably, the dispersion process is a process that includes a bath sonication step. According to FIG. 10, the dispersion process can be comprised by the sub-steps of providing a filtered product containing expanded graphite; providing a mixture of water and a solvent; and dispersing the filtered product containing expanded graphite in a mixture of water and a solvent by a sonication process to obtain a graphene slurry (1); wherein the mixture of water and a solvent includes water in a range between 10% v/v and 40% v/v, and solvent is in a range between 60% v/v and 90% v/v. This allows to exfoliate the expanded graphite material due to the interaction between the mixture of solvent and water with graphite to achieve dispersion with high population of monolayers. In another aspect, according to FIG. 11, the present disclosure is related to a method for producing a thermoelectric device (2) comprising the steps of providing a graphene slurry (1); providing a support layer (4) having a first surface (4A) and a second surface (4B); and depositing at least one layer of the graphene slurry (1) on the first surface (4A) of the support layer (4) by means of a deposition process to obtain a deposited thermoelectric material (3) on a support layer (4) conforming a thermoelectric device (2). This allows to harness the anisotropic thermoelectric properties of graphene while assuring electrical conductivity in the perpendicular direction.

Particularly, the deposited graphene slurry (1) includes a solid part comprising few-layer graphene (6) with a concentration in a range between 80% and 99%; and a mixture of water and a solvent including water in a range between 10% v/v and 40% v/v, and solvent in a range between 90% v/v and 60% v/v.

Preferably, the provided support layer (4) can be formed from a flexible material, such as fabric. Also, the support layer (4) can be a fabric material, for example, a fabric material including at least 50% of polymeric material.

According to the above, the deposited graphene slurry (1) can have a viscosity between 0.11 Pa*s and 0.68 Pa*s. This allows different methods of deposition of the slurry while maintaining consistent deposition quality throughout a deposition or a printing job.

In an embodiment of the present disclosure, the deposited graphene slurry (1) further comprises an additive with a Seebeck coefficient near room temperature between 1 μV/K and 1000 μV/K, for example, bismuth telluride (Bi₂Te₃), or other materials known to a person skilled in the art.

The deposition process can be a physical deposition method selected among the group comprising blade coating, roll-to-roll coating, screen printing, or other physical deposition methods known to a person skilled in the art.

In one embodiment of the present disclosure, and according to FIG. 1, the deposition process is a screen-printing method, thus, allowing to integrate the process into common fabrication lines, for example, allowing to integrate the deposition process with current methods for producing clothing garments.

The deposition process could be a multiple step deposition process, in other words, it can be repeated to achieve a thermoelectric device (2) with more than one layer of the thermoelectric material (3) stacked on top of each other to achieve full coverage of the support material (4). By adding more layers of the thermoelectric material (3) to the configuration of the thermoelectric device (2) it is possible to reduce the perpendicular and surface electrical resistance of the overall thermoelectric device (2). When the thermoelectric device (2) has a lower surface electrical resistance the thermoelectric device (2) is more efficient, this is because when there is lower surface electrical resistance, conductivity is improved, thus, there are less electrical power loses.

In another embodiment of the present disclosure, at least one layer of the graphene slurry (1) can be deposited on the second surface (4B) of the support layer (4). The deposition process can be a physical deposition method selected among the group comprising blade coating, roll-to-roll coating, and screen printing, or other physical deposition methods known to a person skilled in the art. Preferably, the deposition process is screen-printing.

In another embodiment of the present disclosure, before the step of depositing the at least one layer of the graphene slurry (1) on the first surface (4A) of the support layer (4), and before depositing the at least one layer of the graphene slurry (1) on the second surface (4B) of the support layer (4), the method comprises the steps of providing a sealing material (5); and depositing at least one layer of the sealing material (5) on the first surface (4A) of the support layer (4) by means of a deposition process to obtain a support layer (4) with a layer of a sealing material (5).

The deposited sealing material (5) can be a surface primer selected among the group comprising fabric medium, dye fixatives, stabilizers, adhesive primers, gesso, or other materials known to a person skilled in the art. Preferably, the deposited sealing material (5) can be gesso.

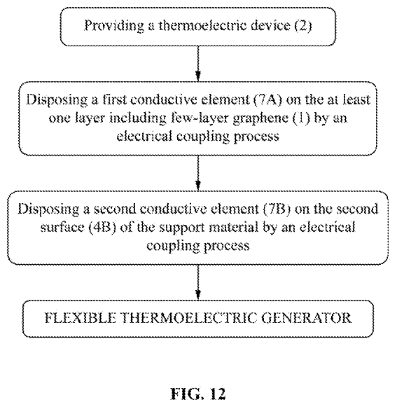

According to FIG. 12, in another aspect the present disclosure is related to a method for producing flexible thermoelectric generator comprising the steps of providing a thermoelectric material (3) comprising a support layer (4) having a first surface (4A) and a second surface (4B), a layer of a sealing material (5) disposed on the first surface (4A) of the support layer (4), and a layer including few-layer graphene (6) with a concentration in a range between 80% and 99%; disposing a first conductive element (7A) on the at least one layer including few-layer graphene (6) by an electrical coupling process; and disposing a second conductive element (7B) on the second surface (4B) of the support layer (4) by an electrical coupling process.

Preferably, the provided support layer (4) can be formed from a flexible material, such as fabric. Also, the support layer (4) can be a fabric material, for example, a fabric material including at least 50% of polymeric material.

The electrical coupling method can be selected among the group of pressure contact, taping, metal deposition, or other electrical coupling methods known to a person skilled in the art.

In an embodiment of the present disclosure, the electrical coupling method can be metal deposition. This allows to minimize the effect of resistance between the thermoelectric material (3) and the conductive elements (7A, 7B) where the produced electrical voltage is conduced.

The flexible thermoelectric generator can be manufactured with different effective printed area by connecting various flexible thermoelectric generators in series.

In an embodiment of the present disclosure, different flexible thermoelectric generators can be connected in series by connecting the first conductive element (7A) of a flexible thermoelectric generator to the second conductive element (7B) of another flexible thermoelectric generator, or by stacking various additional layers of thermoelectric material (3) and conductive elements (7A, 7B) of a flexible thermoelectric generator, or by combining any of the abovementioned methods. As a result, the generated voltage of each individual flexible thermoelectric generator can be added and/or multiplied according to the resistance of each generator.

### EXAMPLES

### Example 1

A graphene slurry (1) was produced following the following steps:
obtaining a filtered product containing expanded graphite from a graphitic material by an expansion process; and
obtaining a graphene slurry (1) from the filtered product containing expanded graphite obtained in the previous step by a dispersion process.

The expansion process was performed by an electrochemical process comprising the following sub-steps:
providing 80 ml of H2_{S}O₄ at a concentration of 0.1M;

providing an anode comprising a graphite foil with a thickness of 0.254 mm cut into pieces with dimension 6.5 cm×1.5 cm; and a cathode comprising a platinum auxiliary wire (Basi MW-1032) with a length of 7.5 cm;
immersing the anode and the cathode in the acidic solution;
applying 8.5V with a current between 0.6 A and 0.9 A, direct current, between the cathode and the anode to obtain a mixture including expanded graphite and H2_{S}O₄.

The expansion process was conducted until the current meter dropped to 0 A and was repeated 3 times before removing the excess of the H₂SO₄. To remove the H₂SO₄, filtration using vacuum was performed using a polyvinylidene fluoride (PVDF) filter with a pore size of 0.22 μm. When the filtration process of the H₂SO₄ was finished, the excess of acid was eliminated by adding de-ionized Water (Type I) to the expanded graphite and filtering the water to obtain a filtered product containing expanded graphite.

The dispersion process was performed by adding the filtered product containing expanded graphite previously obtained to a mixture of 30% water and a 70% NMP (surface tension 40.7 mN/m) and dispersing the filtered product containing expanded graphite by a sonication process at 40 kHz for 5 h to obtain a graphene slurry (1).

The obtained graphene slurry (1) had the following characteristics:
volume 30 ml approximately;
70.97% mixture of water and NMP;
29.02% solid part, wherein the solid part is composed of 95.4% bilayer and monolayer graphene and 4.6% of non-exfoliated material (v. gr. Graphite, expanded graphite or graphene with more than 3 layers).

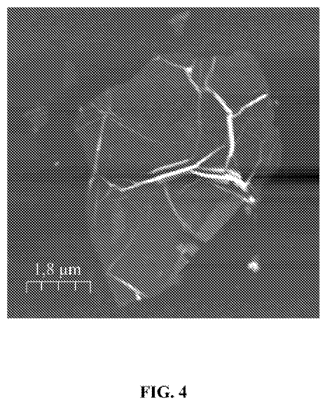

The isolated graphene sheets obtained are shown in FIG. 4.

### Example 2

A graphene slurry (1) was produced following the steps in EXAMPLE 1, wherein the dispersion process was performed by adding the filtered product containing expanded graphite to a mixture of 30% water and a 70% DMF (surface tension 37.1 mN/m).

The obtained graphene slurry (1) had the following characteristics:
volume 30 ml approximately;
69.65% mixture of water and DMF;
30.35% solid part, wherein the solid part is composed of 87.5% bilayer and monolayer graphene and 12.5% of non-exfoliated material;
viscosity of 0.388±0.04 Pa*s at 30 rpm, 0.242±0.02 Pa*s at 60 rpm, 0.148±0.01 Pa*s at 120 rpm, and 0.11±0.005 Pa*s at 240 rpm.

### Example 3

A graphene slurry (1) was produced following the steps in EXAMPLE 1, wherein the dispersion process was performed by adding the filtered product containing expanded graphite to a mixture of 30% water and a 70% Cyrene (surface tension 40.5 mN/m).

The obtained graphene slurry (1) had the following characteristics:
volume 30 ml approximately;
74.1% mixture of water and Cyrene;
25.9% solid part, wherein the solid part is composed of 87.5% bilayer and monolayer graphene and 12.5% of non-exfoliated material;
viscosity 0.68±0.08 Pa*s at 15 rpm, 0.436±0.04 Pa*s at 30 rpm, 0.304±0.01 Pa*s at 60 rpm, and 0.236±0.01 Pa* at 120 rpm;

### Example 4

A thermoelectric device (2) was produced by depositing 2 layers of the graphene slurry (1) of EXAMPLE 3 on a fabric material comprising 100% polyester. The graphene slurry (1) layers were deposited using screen-printing and, after each deposition, the deposited graphene slurry (1) was left to dry for 2 hours to obtain a thermoelectric material (3) disposed on the fabric material.

The obtained thermoelectric device (2) had the following characteristics:
a portion of the thermoelectric material (3) embedded in the fabric material;
thickness of 0.53mm;
printed area with the thermoelectric material of 20 cm×1.5 cm;
superficial electrical resistance of 20 kOhm at 2 cm of distance, 57.96±15.56 kOhm at 4 cm of distance, 103.93±55.1 kOhm at 6 cm of distance;
perpendicular electrical resistance approximately 293 kOhm;
Seebeck coefficient (in an area of 10 mm×20mm): −50.25±1.48 μV/K
thermal conductivity 13.57 W/mK.

### Example 5

A thermoelectric device (2) was produced by depositing 4 layers of the graphene slurry (1) of EXAMPLE 3 on a fabric material comprising 100% polyester. The graphene slurry (1) layers were deposited according to the method in the EXAMPLE 4.

The obtained thermoelectric device (2) had the following characteristics:
a portion of the thermoelectric material (3) embedded in the fabric material;
thickness of 0.53 mm;
printed area with the thermoelectric material of 20 cm×1.5 cm;
superficial electrical resistance of 60.05±0.07 kOhm at 2 cm of distance, 123.53 ±87.47 kOhm at 4 cm of distance, 146.05±103.94 kOhm at 6 cm of distance,
perpendicular electrical resistance approximately 29.2 kOhm;
Seebeck coefficient (in an area of 10 mm×20 mm) −44±2.0 μV/K;
thermal conductivity 0.18±0.09 W/mK.

### Example 6

The thermoelectric device (2) of FIG. 5 was produced by depositing 10 layers of the graphene slurry (1) of EXAMPLE 3 on a fabric material comprising 100% polyester. The graphene slurry (1) layers were deposited according to the method in the EXAMPLE 4.

The obtained thermoelectric device (2) had the following characteristics:
a portion of the thermoelectric material (3) embedded in the fabric material and other portion when through the support layer (polyester) and reached the other side (4B);
printed area with the thermoelectric material of 20 cm×1.5 cm;
superficial electrical resistance of 3.3±1.13 kOhm at 2 cm of distance, 4.71±2.01 kOhm at 4 cm of distance, 6.39±2.05 kOhm at 6 cm of distance, 7.52±2.17 kOhm at 8 cm of distance, 8.34±1.90 kOhm at 10 cm of distance;
perpendicular electrical resistance approximately 9.5 kOhm;
Seebeck coefficient (in an area of 10 mm×20 mm) −19.35±5.6 μV/K;
thermal conductivity 37.09 W/mK.

### Example 7

A thermoelectric device (2) was produced by depositing 3 layers of gesso and 7 layers of the graphene slurry (1) of EXAMPLE 3 on a fabric material comprising 100% polyester. Each layer of the sealing material was deposited using a brush. The graphene slurry (1) layers were deposited according to the method in the EXAMPLE 4, the deposited graphene slurry (1) was left to dry for 4 hours.

The obtained thermoelectric device (2) had the following characteristics:
no portion of the thermoelectric material (3) embedded in the fabric material;
printed area with the thermoelectric material of 20 cm×1.5 cm;
Superficial electrical resistance of 31.28±6.36 kOhm at 2 cm of distance, 68.36±15.63 kOhm at 4 cm of distance, 83.74±14.35 kOhm at 6 cm of distance, 96.06±20.93 kOhm at 8 cm of distance, 104.26±11.88 kOhm at 10 cm of distance.

### Example 8

A thermoelectric device (2) was produced by depositing 8 layers of the graphene slurry (1) of EXAMPLE 3 on a fabric material comprising 50% polyester and 50% cotton. The graphene slurry (1) layers were deposited according to the method of EXAMPLE 4.

The obtained thermoelectric device (2) had the following characteristics:
a portion of the thermoelectric material (3) embedded in the fabric material, other portion when through the support layer (polyester) and reached the other side (4B);
printed area with the thermoelectric material of 20 cm×1.5cm;
superficial electrical resistance of 3.30±1.13 kOhm at 2 cm of distance, 4.71±2.01 kOhm at 4 cm of distance, 6.39±2.05 kOhm at 6 cm of distance, 7.52±2.17 kOhm at 8 cm of distance, 8.35±1.90 kOhm at 10 cm of distance;
Seebeck coefficient (in an area of 10 mm×20 mm) 0.115 m V/K;
thermal conductivity 2.80 W/mK.

### Example 9

A flexible thermoelectric generator was produced using the device of EXAMPLE 7. The generator was manufactured by disposing a 300 nm silver layer on the thermoelectric material of the device and disposing a 300 nm silver layer on the fabric material of the device. Both silver layers were deposited by means of vacuum evaporation.

The obtained thermoelectric generator had the following characteristics:
printed area with graphene of 18 cm²;
thickness 0.52 mm;
superficial resistance of 14.5 Ohms on the first surface (4A) and 76.0 Ohms on the second surface;
perpendicular resistance of 60 kOhms;
Seebeck coefficient −1.88 mV/K.

### Example 10

A flexible thermoelectric generator was produced using the device of EXAMPLE 7. The generator was manufactured by disposing a 300 nm silver layer on the thermoelectric material of the device and disposing a 300 nm silver layer on the fabric material of the device. Both silver layers were deposited by means of vacuum evaporation.

The obtained thermoelectric generator had the following characteristics:
printed area with graphene of 9 cm²;
thickness 0.50 mm;
superficial resistance of 4.50 hms on the first surface (4A) and 264.70 hms on the second surface;
perpendicular resistance of 160 kOhms;
Seebeck coefficient −1.380 m V/K.

### Example 11

A flexible thermoelectric generator was produced using the device of EXAMPLE 8. The generator was manufactured by disposing a 300 nm silver layer on the thermoelectric material of the device and disposing a 300 nm silver layer on the fabric material of the device. Both silver layers were deposited by means of vacuum evaporation.

The obtained thermoelectric generator had the following characteristics:
printed area with graphene 22.5 cm²;
thickness 0.26 mm;
superficial resistance of 6 Ohms on the first surface (4A) and 14.5 Ohms on the second surface;
perpendicular resistance of 6.5 Ohms;
Seebeck coefficient −4.93 μV/K.

### Example 12

A flexible thermoelectric generator was produced using the device of EXAMPLE 8. The generator was manufactured by disposing a 300 nm silver layer on the thermoelectric material of the device and disposing a 300 nm silver layer on the fabric material of the device. Both silver layers were deposited by means of vacuum evaporation. Additionally, copper tape was stuck on both silver layers.

The obtained thermoelectric generator had the following characteristics:
printed area with graphene of 22.5 cm²;
thickness 0.29 mm;
superficial resistance of 0.30 hms on the first surface (4A) and 0.30 hms on the second surface;
perpendicular resistance of 3.8 Ohms;
Seebeck coefficient −4.15 μV/K.

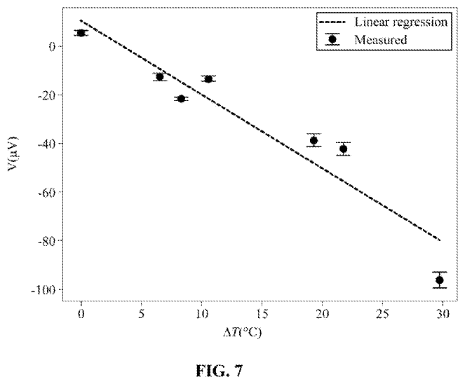

The obtained flexible thermoelectric generator was able to produce energy as shown in FIG. 7

### Example 13

A flexible thermoelectric generator was produced by connecting in series eight of the devices of EXAMPLE 11, with a size of 1.5 cm×1.5 cm. The generator was manufactured by disposing a 300 nm silver layer on each of the thermoelectric material of the devices and disposing a 300 nm silver layer on the fabric material of the devices. Both silver layers were deposited by means of vacuum evaporation.

The obtained thermoelectric generator had the following characteristics:
printed area with graphene 18 cm²;
thickness 0.26 mm;
perpendicular resistance of 100 kOhms;
Seebeck coefficient −0.1 mV/K

### Example 14

A Flexible thermoelectric generator was produced by stacking, one on the other, two generators. For this, eight depositions of graphene slurry (1) were made on a fabric material comprising 50% polyester and 50% cotton using screen-printing and, after each deposition, the deposited graphene slurry (1) was left to dry for 2 hours to obtain a thermoelectric material (3) disposed on the fabric material. Later, 300 nm of silver were deposited on the thermoelectric material by means of vacuum evaporation. After that, four depositions of graphene slurry (1) were made using screen-printing printing and, after each deposition, the deposited graphene slurry (1) was left to dry for 2 hours to obtain a thermoelectric material (3) disposed on the silver layer. Finally, two silver depositions were made. The first one was made by evaporating 300 nm of silver on the outer layer of thermoelectric material and the second one was made by evaporating 300 nm of silver on the second surface of the fabric material of the device.

The obtained thermoelectric generator had the following characteristics:
thickness 0.35 mm;
perpendicular resistance of 10.90 hms;
Seebeck coefficient −8.67 μV/K

It is to be understood that the present disclosure is not limited to the modes described and illustrated, for as will be evident to a person skilled in the art, there are variations and modifications possible which do not depart from the spirit of the disclosure, which alone is defined by the following claims.

1. A graphene slurry (1), comprising:
a solid part in a range between 5% and 40%; and
a mixture of water and a solvent in a range between 65% and 75%;
wherein the solid part comprises graphene including few-layer graphene (6) with a concentration in a range between 80% and 99%; and
wherein the mixture of water and a solvent comprises water is in a range between 10% v/v and 40% v/v, and solvent is in a range between 60% v/v and 90% v/v.

2. The graphene slurry (1) of claim 1, wherein the solid part further includes graphite and expanded graphite.

3. The graphene slurry (1) of claim 1, wherein the solvent is a solvent with a surface tension between 37 mN/m and 41 mN/m.

4. The graphene slurry (1) of claim 1, further comprising bismuth telluride (Bi₂Te₃) with a concentration in a range between 2% and 20%.

5. A thermoelectric material (3), comprising at least one layer including few-layer graphene (6) with a concentration in a range between 80% and 99%.

6. The thermoelectric material (3) of claim 5, wherein the few-layer graphene (6) has a concentration of bilayer graphene greater than 80%.

7. The thermoelectric material (3) of claim 5, further comprising bismuth telluride (Bi₂Te₃) with a concentration in a range between 2% and 20%.

8. A thermoelectric device (2), comprising:
a support layer (4) having a first surface (4A) and a second surface (4B);
at least one layer of thermoelectric material (3) disposed on the support layer (4);
wherein, the thermoelectric material (3) comprises at least one layer including few-layer graphene (6) with a concentration in a range between 80% and 99%.

9. The thermoelectric device (2) of claim 8, wherein at least one layer of thermoelectric material (3) is disposed on the first surface (4A) of the support layer (4).

10. The thermoelectric device (2) of claim 9, wherein a portion of the thermoelectric material (3) is embedded in the support layer (4).

11. The thermoelectric device (2) of claim 10, wherein at least one layer of thermoelectric material (3) is disposed on the second surface (4B) of the support layer (4).

12. The thermoelectric device (2) of claim 8, further comprising a first conductive element (7A) disposed on the at least one layer of thermoelectric material (3) and a second conductive element (7B) disposed on the second surface (4B) of the support layer (4).

13. The thermoelectric device (2) of claim 8, further comprising a layer of a sealing material (5) disposed between the support layer (4) and the thermoelectric material (3).

14. The thermoelectric device (2) of claim 13, wherein the sealing material (5) is gesso.

15. The thermoelectric device (2) of claim 8, wherein the support layer (4) is a fabric material.

16. The thermoelectric device (2) of claim 15, wherein the fabric material includes at least 50% of a polymeric material.

17. A method for producing a graphene slurry (1) comprising the following steps:
obtaining a filtered product containing expanded graphite from a graphitic material by an expansion process; and
obtaining a graphene slurry (1) from the filtered product containing expanded graphite obtained in the previous step by a dispersion process;
wherein the graphene slurry (1) includes a solid part comprising few-layer graphene (6), and a mixture of water and a solvent;
wherein the few-layer graphene (6) has a concentration in a range between 80% and 99%; and
wherein the mixture of water and solvent includes water in a range between 10% v/v and 40% v/v, and solvent in a range between 60% v/v and 90% v/v.

18. The method of claim 17, wherein the expansion process is an electrochemical expansion process comprising the following sub-steps:
providing an acidic solution;
providing an anode and a cathode, wherein the anode comprises a graphitic material and the cathode comprises a non-oxidizing material;
immersing the anode and the cathode in the acidic solution;
applying an electrical power between the cathode and the anode to obtain a mixture including expanded graphite and the acidic solution; and
removing the excess of the acidic solution by means of filtering the mixture including expanded graphite and the acidic solution while adding water to obtain a filtered product containing expanded graphite.

19. The method of claim 17, wherein the dispersion process comprises the following sub-steps:
providing a filtered product containing expanded graphite;
providing a mixture of water and a solvent; and
dispersing the filtered product containing expanded graphite in a mixture of water and a solvent by a sonication process to obtain a graphene slurry (1);
wherein the mixture of water and a solvent includes water in a range between 10% v/v and 40% v/v, and solvent is in a range between 60% v/v and 90% v/v.

20. The method of claim 17, wherein the solvent has a surface tension between 30 mN/m and 50 mN/m.

21. A method for producing a thermoelectric device (2) comprising the following steps:
providing a graphene slurry (1);
providing a support material having a first surface (4A) and a second surface (4B); and
depositing at least one layer of the graphene slurry (1) on the first surface (4A) of the support material by means of a deposition process to obtain a thermoelectric device (2);
wherein the graphene slurry (1) includes a solid part comprising few-layer graphene (6) and a mixture of water and a solvent;
wherein the solid part comprises graphene including few-layer graphene (6) with a concentration in a range between 80% and 99%; and
wherein the mixture of water and solvent includes water in a range between 10% v/v and 40% v/v, and solvent in a range between 60% v/v and 90% v/v.

22. The method of claim 21, wherein the graphene slurry (1) has a viscosity between 0.11 Pa*s and 0.68 Pa*s.

23. The method of claim 21, wherein the deposition process is screen printing.

24. The method of claim 21, wherein the graphene slurry (1) further comprises bismuth telluride (Bi₂Te₃).

25. The method of claim 21, wherein the support layer (4) is a fabric material.

26. The method of claim 25, wherein the fabric material includes at least 50% of a polymeric material.

27. The method of claim 21, wherein the step of depositing the at least one layer of the graphene slurry (1) on the first surface (4A) of the support material further comprises depositing at least one layer of the graphene slurry (1) on the second surface (4B) of the support material by means of a deposition process.

28. The method of claim 21, further comprising the following steps before depositing the at least one layer of the graphene slurry (1) on the first surface (4A) of the support material:
providing a sealing material (5); and
depositing at least one layer of the sealing material (5) on the first surface (4A) of the support material by means of a deposition process to obtain a support material with a layer of a sealing material (5).

29. The method of claim 28, wherein the sealing material (5) is gesso.

30. A method for producing flexible thermoelectric generator comprising the following steps:
providing a thermoelectric device (2) comprising a support layer (4) having a first surface (4A) and a second surface (4B), a layer of a sealing material (5) disposed on the first surface (4A) of the support material, and a layer including few-layer graphene (6) with a concentration in a range between 80% and 99%;
disposing a first conductive element (7A) on the at least one layer including few-layer graphene (6) by an electrical coupling process; and
disposing a second conductive element (7B) on the second surface (4B) of the support layer (4) by an electrical coupling process.

31. The method of claim 30, wherein the electrical coupling process is a metal deposition process.

32. The method of claim 30, wherein the support material is a fabric material.

33. The method of claim 32, wherein the fabric material includes at least 50% of a polymeric material.
